(19) United States
(12) Patent Application Publication
(10) Pub. No.: US 2019/0097671 A1
(43) Pub. Date: Mar. 28, 2019

(54) CONVERGED TRANSMITTER ARCHITECTURE WITH REDUCED POWER CONSUMPTION

(71) Applicant: Apple Inc., Cupertino, CA (US)

(72) Inventors: Ronald W. Dimpflmaier, Los Gatos, CA (US); Rastislav Vazny, Sunnyvale, CA (US); Lydi R. Smaini, San Jose, CA (US)

(21) Appl. No.: 15/715,739

(22) Filed: Sep. 26, 2017

(51) Int. Cl. H04B 1/44; H04B 1/04; H04W 52/52; H01L 23/66; H01Q 7/00; H03F 3/24; H04B 1/3827

(52) U.S. Cl. CPC H04B 1/44; H04B 1/0458; H04W 52/52; H01L 23/66; H03F 2200/321; H03F 3/24; H04B 1/3827; H04B 2001/0408; H03F 2200/451; H01Q 7/005

(57) ABSTRACT

The present disclosure relates to radiofrequency (RF) communications systems that may operate efficiently over a broad range of signal output levels. Electronic devices may employ amplification circuitry in the communication RF systems to provide output signal power. For example, amplification provided by external power amplifiers disposed in front-end modules may be more efficient at a higher range of output signal power, but may be inefficient at a lower range of output signal power. The disclosure relates to architectures for RF communication systems having transceivers and front-end modules that may provide power-efficient over broad ranges. Front-end modules may, for example, be managed to disable and/or enable external power amplifiers based of the output signal power. Transceivers may, for example, include internal power amplifier which may provide amplification for low output signals, and may operate as a driver to the external power amplifier of the front-end module for high output signals. Methods for managing the circuitry are also discussed.

### BACKGROUND

The present disclosure relates generally to radiofrequency (RF) communications circuitry, and more specifically, to integrated transmitter architectures that may be used by electrical devices to connect to multiple types of networks over a broad range of output power levels.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Many electronic devices may communicate over diverse types of wireless networks, from long-distance cellular networks to short-distance local connectivity networks. For example, devices such as cell phones, portable computers, electronic tablets, smartwatches, and other wearable devices may be used to initiate calls and retrieve internet data over a cellular network while also connecting to nearby peripheral devices such as headsets and/or heart rate sensors. To that end, these electronic devices may employ circuitry dedicated to access the radio frequency (RF) networks. However, different networks may have different specifications related to modulation, frequency bands, and signal power. For example, cellular networks may use large power signal outputs to connect to electronic devices over large distances (e.g., over a mile), while Bluetooth connections may be established with low-power signals limited to shorter distances (e.g., less than 40 yards). To that end, electronic devices may employ a dedicated module for each network type. As an example, RF communication circuitry for cellular networks may employ front-end modules having strong power amplifiers, which may be unnecessary for coupling to networks with low power specification. Accordingly, electronic devices that are capable of joining cellular and connectivity networks may have multiple RF communication systems. The presence of multiple RF communication modules in an electronic device may lead to duplication of substantial part of the circuitry leading to inefficient space utilization and higher power consumption.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Electronic devices may connect to multiple wireless networks by employing radio frequency (RF) circuitry. Since different networks may have different specifications, these devices may employ multiple RF modules to couple to the different networks. Architectures having multiple RF modules may lead to inefficiencies due to increased floorplan space in a printed circuit board and higher power demands from duplication of the circuitry.

Embodiments described herein relate to integrated RF communication systems that may operate efficiently over a broad range of output powers, which may allow a single RF communication system to operate with many different types of wireless networks. Certain RF communication systems described herein may employ internal power amplifiers in the transceiver that provide amplification to join networks in a relatively low-output-power range. Certain systems may employ external power amplifiers to provide amplifications to join networks in a relatively high-output-power range. In some systems, the internal power amplifier may operate as a power driver (e.g., provide driver amplification) to a single-stage power amplifier, which may reduce the energy consumption for the system. Methods and systems described herein also provide flexible control for RF transceivers and/or a front-end module to allow switching between multiple channels of the network by allowing switching the signals for time-coding, time-multiplexing, and/or filtering the signals to adjust carrier frequencies.

### BRIEF DESCRIPTION OF THE DRAWINGS

Various aspects of this disclosure may be better understood upon reading the following detailed description and upon reference to the drawings in which:

FIG. 1 is a schematic block diagram of an electronic device that may benefit from the use of radio frequency (RF) communication systems described herein, in accordance with an embodiment;

FIG. 2 is a perspective view of a notebook computer representing an embodiment of the electronic device of FIG. 1;

FIG. 3 is a front view of a hand-held device representing another embodiment of the electronic device of FIG. 1;

FIG. 4 is a front view of another hand-held device representing another embodiment of the electronic device of FIG. 1;

FIG. 5 is a front view of a desktop computer representing another embodiment of the electronic device of FIG. 1;

FIG. 6 is a front view and side view of a wearable electronic device representing another embodiment of the electronic device of FIG. 1;

FIG. 7 is a schematic block diagram of an RF communication system that may be used in the electronic device of FIG. 1 to join multiple networks, in accordance with an embodiment;

FIG. 8 is a chart illustrating DC power consumption of an RF communication system such as that of FIG. 7, in accordance with an embodiment;

FIG. 9 is a schematic block diagram of an RF communication system that may be used in the electronic device of FIG. 1 to join multi-channel networks, in accordance with an embodiment;

FIG. 10 is a schematic block diagram of a low-power RF communication that may be used in the electronic device of FIG. 1 to join multi-channel networks, in accordance with an embodiment;

FIG. 11 is a schematic block diagram of an integrated RF communication system which may be used in the electronic device of FIG. 1 to join multiple networks, in accordance with an embodiment;

FIG. 12 is a chart illustrating DC power consumption of an RF communication system such as that of FIG. 11, in accordance with an embodiment; and

FIG. 13 is a flow chart of a method to operate an integrated RF communication system, such as those of FIG. 7, 9, 10, or 11, in accordance with an embodiment.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Many electronic devices may access wireless networks to exchange data with other electronic devices. These wireless networks, which may include cellular networks (e.g., 4G standards such as Long Term Evolution or LTE, 5G standards such as New Radio or 5G NR) and/or connectivity networks (e.g., IEEE 802.3 or WiFi, Bluetooth), may be implemented by establishing radio frequency (RF) connections between electronic devices. In order to establish such connections, the electronic devices may include RF communication systems, which may include transmission and reception circuitry coupled to an antenna. The circuitry may include a transceiver module, which may perform encoding/decoding and modulation/demodulation tasks, as well as digital-to-analog and analog-to-digital conversion. The transceiver module may be coupled to the antenna by a front-end module (FEM), which may provide filtering and/or power amplification capabilities to the RF communication system.

Different networks may have different signal power requirements. For example, cellular networks may have signal power requirements that may be satisfied with the use of external power amplification, which may be placed in the front-end module (FEM). By contrast, local wireless networks may have signal power requirements that may be satisfied by power amplification provided by an internal power amplifier, which may be placed in the RF transceiver. Electronic devices that are capable of joining multiple networks may employ dedicated components for each network type and/or network type. Certain systems may, for example employ multiple RF transceivers and/or multiple front-end modules based on signal power requirements, band, channel, or other network requirements.

The methods and systems described herein relate to integrated, power-efficient RF communication systems that may operate over a wide range of signal power specifications. These systems may include integrated front-end modules that can support multiple types of networks with different power specifications in a power efficient manner. These front-end modules may be coupled to RF transceivers having internal power amplifiers, which may be implemented using semiconductor technology (e.g., metal-oxide semiconductor or MOS, complementary metal-oxide semiconductor or CMOS). Embodiments that combine the integrated front-end modules with RF transceivers with internal power amplifiers may employ the internal power amplifier and bypass the external amplifier when connecting to networks with low power specification and employ the front-end module power amplifier when connecting to networks with high power specification. In some implementations, the integrated amplifier in the transceiver may perform as a driver for a single-stage external power amplifier disposed in the front-end module. As detailed below, the front-end module may also include filter banks to increase the flexibility in the available networks. The front-end module may also be coupled to envelope-tracking circuitry that adjusts the amplification of the external power amplifier dynamically, improving power efficiency when transmitting high power signals.

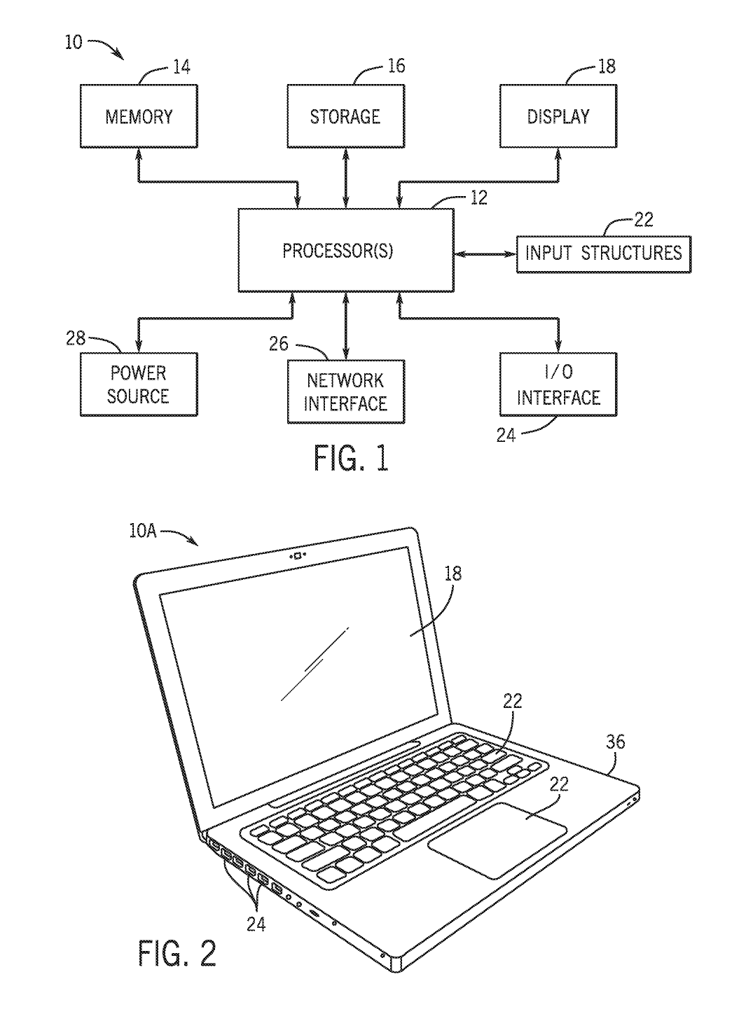

With the foregoing in mind, there are many suitable electronic devices that may employ a converged transmitter architecture to reduce power and save footprint space. Turning first to FIG. 1, an electronic device 10 according to an embodiment of the present disclosure may include, among other things, one or more processor(s) 12, memory 14, nonvolatile storage 16, a display 18, input structures 22, an input/output (I/O) interface 24, a network interface 26, and a power source 28. The various functional blocks shown in FIG. 1 may include hardware elements (including circuitry), software elements (including computer code stored on a computer-readable medium) or a combination of both hardware and software elements. It should be noted that FIG. 1 is merely one example of a particular implementation and is intended to illustrate the types of components that may be present in electronic device 10.

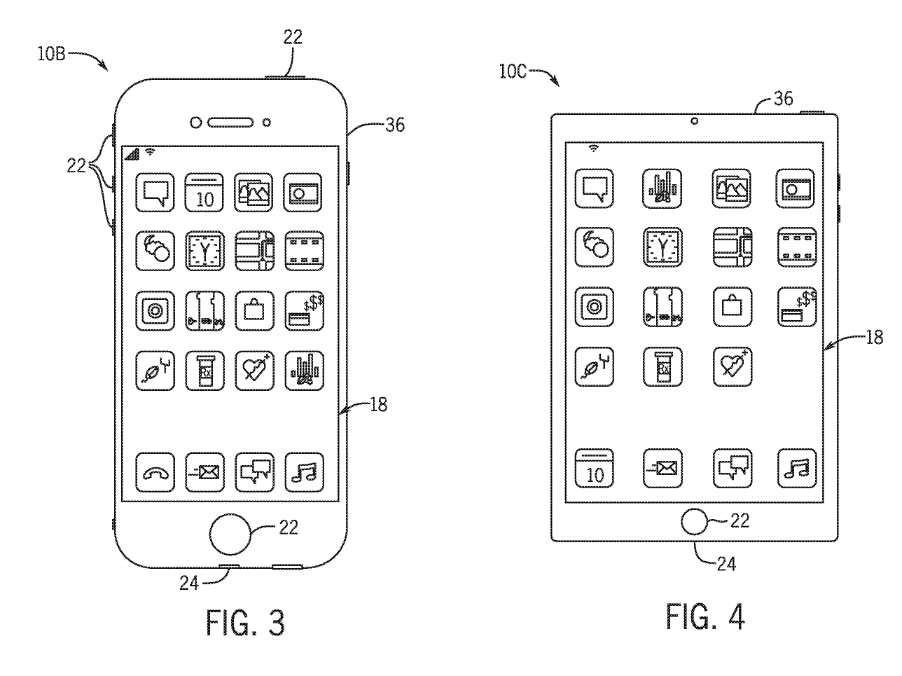

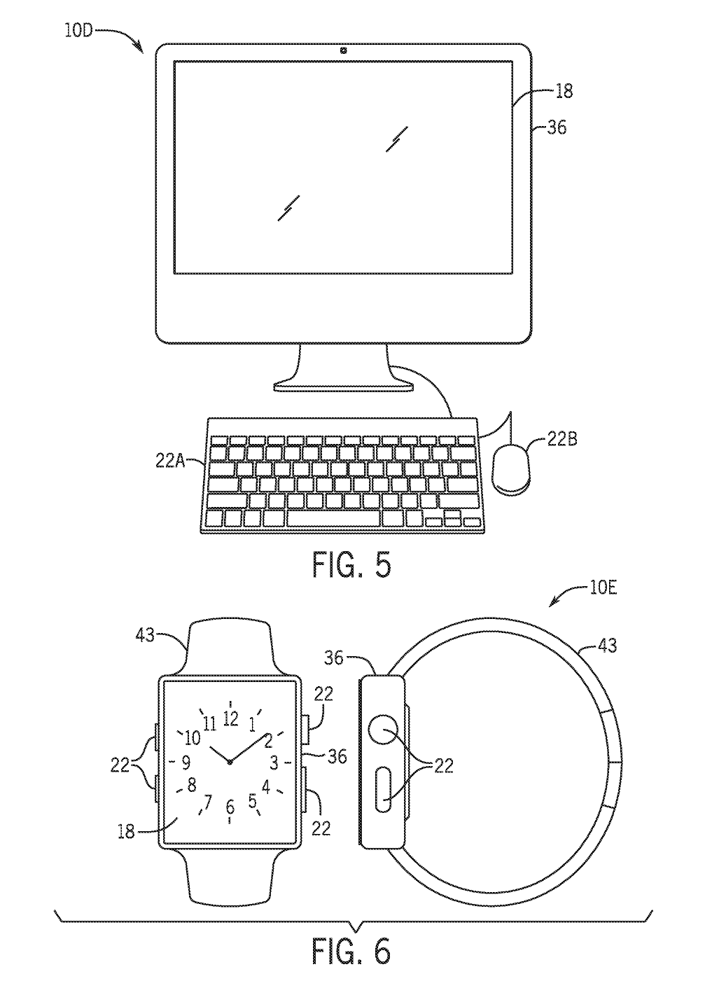

By way of example, the electronic device 10 may represent a block diagram of the notebook computer depicted in FIG. 2, the handheld device depicted in FIG. 3, the handheld device depicted in FIG. 4, the desktop computer depicted in FIG. 5, the wearable electronic device depicted in FIG. 6, or similar devices. It should be noted that the processor(s) 12 and other related items in FIG. 1 may be generally referred to herein as “data processing circuitry.” Such data processing circuitry may be embodied wholly or in part as software, firmware, hardware, or any combination thereof. Furthermore, the data processing circuitry may be a single contained processing module or may be incorporated wholly or partially within any of the other elements within the electronic device 10.

In the electronic device 10 of FIG. 1, the processor(s) 12 may be operably coupled with the memory 14 and the nonvolatile storage 16 to perform various algorithms. Such programs or instructions executed by the processor(s) 12 may be stored in any suitable article of manufacture that includes one or more tangible, computer-readable media at least collectively storing the instructions or routines, such as the memory 14 and the nonvolatile storage 16. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor(s) 12 to enable the electronic device 10 to provide various functionalities.

In certain embodiments, the display 18 may be a liquid crystal display (LCD), which may allow users to view images generated on the electronic device 10. In some embodiments, the display 18 may include a touch screen, which may allow users to interact with a user interface of the electronic device 10. Furthermore, it should be appreciated that, in some embodiments, the display 18 may include one or more organic light emitting diode (OLED) displays, or some combination of LCD panels and OLED panels.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. The network interface 26 may include, for example, one or more interfaces for a personal area network (PAN), such as a Bluetooth network, for a local area network (LAN) or wireless local area network (WLAN), such as an 802.11x Wi-Fi network, and/or for a wide area network (WAN), such as a 3rd generation (3G) cellular network, universal mobile telecommunication system (UMTS), 4th generation (4G) cellular network, long term evolution (LTE) cellular network, or long term evolution license assisted access (LTE-LAA) cellular network, 5th generation (5G) cellular network, and/or 5G New Radio (5G NR) cellular network. The network interface 26 may also include one or more interfaces for, for example, broadband fixed wireless access networks (WiMAX), mobile broadband Wireless networks (mobile WiMAX), asynchronous digital subscriber lines (e.g., ADSL, VDSL), digital video broadcasting-terrestrial (DVB-T) and its extension DVB Handheld (DVB-H), ultra-Wideband (UWB), alternating current (AC) power lines, and so forth. For example, network interfaces 26 may include circuitry for accessing wireless networks, and may include RF transceivers, front-end modules, and/or envelope tracking circuitry arranged in the converged architecture detailed below. As further illustrated, the electronic device 10 may include a power source 28. The power source 28 may include any suitable source of power, such as a rechargeable lithium polymer (Li-poly) battery and/or an alternating current (AC) power converter.

In certain embodiments, the electronic device 10 may take the form of a computer, a portable electronic device, a wearable electronic device, or other type of electronic device. Such computers may include computers that are generally portable (such as laptop, notebook, and tablet computers) as well as computers that are generally used in one place (such as conventional desktop computers, workstations, and/or servers). In certain embodiments, the electronic device 10 in the form of a computer may be a model of a MacBook®, MacBook® Pro, MacBook Air®, iMac®, Mac® mini, or Mac Pro® available from Apple Inc. By way of example, the electronic device 10, taking the form of a notebook computer 10A, is illustrated in FIG. 2 in accordance with one embodiment of the present disclosure. The depicted computer 10A may include a housing or enclosure 36, a display 18, input structures 22, and ports of an I/O interface 24. In one embodiment, the input structures 22 (such as a keyboard and/or touchpad) may be used to interact with the computer 10A, such as to start, control, or operate a GUI or applications running on computer 10A. For example, a keyboard and/or touchpad may allow a user to navigate a user interface or application interface displayed on display 18.

FIG. 3 depicts a front view of a handheld device 10B, which represents one embodiment of the electronic device 10. The handheld device 10B may represent, for example, a portable phone, a media player, a personal data organizer, a handheld game platform, or any combination of such devices. By way of example, the handheld device 10B may be a model of an iPod® or iPhone® available from Apple Inc. of Cupertino, Calif. The handheld device 10B may include an enclosure 36 to protect interior components from physical damage and to shield them from electromagnetic interference. The enclosure 36 may surround the display 18. The I/O interfaces 24 may open through the enclosure 36 and may include, for example, an I/O port for a hardwired connection for charging and/or content manipulation using a standard connector and protocol, such as the Lightning connector provided by Apple Inc., a universal service bus (USB), or other similar connector and protocol.

User input structures 22, in combination with the display 18, may allow a user to control the handheld device 10B. For example, the input structures 22 may activate or deactivate the handheld device 10B, navigate user interface to a home screen, a user-configurable application screen, and/or activate a voice-recognition feature of the handheld device 10B. Other input structures 22 may provide volume control, or may toggle between vibrate and ring modes. The input structures 22 may also include a microphone may obtain a user's voice for various voice-related features, and a speaker may enable audio playback and/or certain phone capabilities. The input structures 22 may also include a headphone input may provide a connection to external speakers and/or headphones.

FIG. 4 depicts a front view of another handheld device 10C, which represents another embodiment of the electronic device 10. The handheld device 10C may represent, for example, a tablet computer, or one of various portable computing devices. By way of example, the handheld device 10C may be a tablet-sized embodiment of the electronic device 10, which may be, for example, a model of an iPad® available from Apple Inc. of Cupertino, Calif.

Turning to FIG. 5, a computer 10D may represent another embodiment of the electronic device 10 of FIG. 1. The computer 10D may be any computer, such as a desktop computer, a server, or a notebook computer, but may also be a standalone media player or video gaming machine. By way of example, the computer 10D may be an iMac®, a MacBook®, or other similar device by Apple Inc. It should be noted that the computer 10D may also represent a personal computer (PC) by another manufacturer. A similar enclosure 36 may be provided to protect and enclose internal components of the computer 10D such as the display 18. In certain embodiments, a user of the computer 10D may interact with the computer 10D using various peripheral input devices 22, such as the keyboard 22A or mouse 22B, which may connect to the computer 10D.

Similarly, FIG. 6 depicts a wearable electronic device 10E representing another embodiment of the electronic device 10 of FIG. 1 that may be configured to operate using the techniques described herein. By way of example, the wearable electronic device 10E, which may include a wristband 43, may be an Apple Watch® by Apple, Inc. However, in other embodiments, the wearable electronic device 10E may include any wearable electronic device such as, for example, a wearable exercise monitoring device (e.g., pedometer, accelerometer, heart rate monitor), or other device by another manufacturer. The display 18 of the wearable electronic device 10E may include a touch screen display 18 (e.g., LCD, OLED display, active-matrix organic light emitting diode (AMOLED) display, and so forth), as well as input structures 22, which may allow users to interact with a user interface of the wearable electronic device 10E.

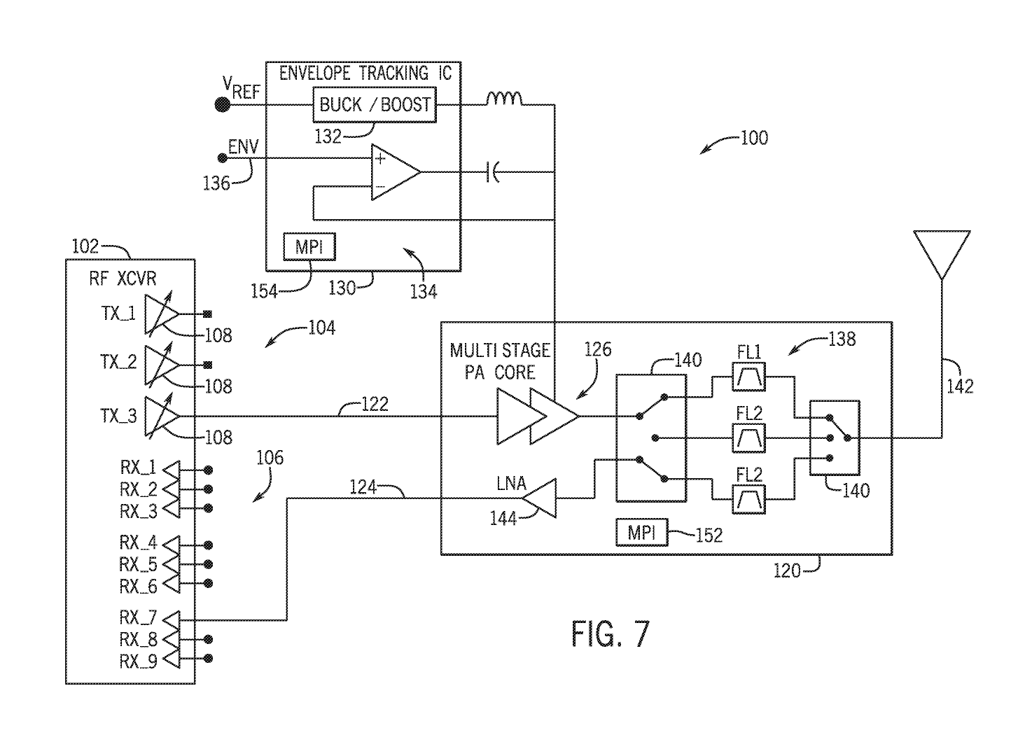

With the foregoing in mind, FIG. 7 illustrates an RF system 100 that may be disposed in the network interface 26 of electronic device 10 to receive and/or transmit data wirelessly to another electronic device. The RF system 100 may, for example, be used by a user equipment (UE) such as a handheld devices 10B or 10C to connect to a cellular network. The RF system 100 may include an RF transceiver 102. The RF transceiver 102 may be a semiconductor transceiver such as a CMOS transceiver. The RF transceiver 102 may have multiple transmission (TX) ports 104 and multiple receiver (RX) ports 106. Note that TX ports 104 may be coupled to pre-amplification circuitry 108 that provide variable gain to the transmitted signal, which may be adjusted based on a target transmit power (e.g., target output signal power). The RF transceiver 102 may be coupled to one or multiple front end modules (FEM), such as a multi-band power amplifier FEM 120. The FEM 120 may receive signals from one of the TX ports 104 via a TX connection 122 and may return signals to one of the RX ports 106 via a RX connection 124.

Signals received via the TX connection 122 may be received in a multi-stage power amplifier (PA) 126 for amplification of the signal. The amplification may be proportional to a voltage received by the multi-stage PA 126. Multi-stage PA 126 may operate in an average power tracking (APT) mode or in an envelope tracking (ET) mode. In the average power tracking mode, the static voltage supplied to the multi-stage PA 126 may be adjusted based on an average power output of the multi-stage PA 126. In the envelope tracking mode, the dynamic voltage supplied to the multi-stage PA 126 may follow (e.g., track) the envelope of the output RF signal. To that end, multi-stage PA 126 may be controlled by an envelope tracking integrated circuit (ETIC) 130. An ETIC 130 may include buck/boost circuitry 132 coupled to error tracking circuitry 134 that may be configured to receive tracking signal 136. Tracking signal 136 may be an envelope signal, such as when multi-stage PA 126 operates in the envelope tracking mode, or an average power signal, such as when multi-stage PA 126 operates in the average power tracking mode. In some situations, the multi-stage PA 126 may also operate in a fixed voltage mode (e.g., APT fixed mode), in which the gain is constant.

In communication circuitry that allow multi-band RF communication, the amplified outgoing signal may be transmitted to a filter bank 138 of FEM 120. The specific filter employed for a particular signal may be selected using switching circuitry 140. The filtered signal may be transmitted wirelessly to another electronic device via an antenna 142. Antenna 142 may also receive signals, which may be filtered using the filter bank 138. The specific filters of filter bank 138 may be selected using the switching circuitry 140. Received signals may be amplified using a low-noise amplifier (LNA) 144, and sent to the RF transceiver 102 via RX connection 124. The FEM 120 may be controlled (e.g., configured) using a standard-compliant controller, such as Mobile Industry Processor Interface (MIPI) RF Front-End Interface (RFFE) controller, which may facilitate integration of the FEM 120 and the electronic device. Note further that the ETIC 130 may be controlled a similar interface, such as the MIPI RFFE, which may facilitate coordination between FEM 120 and ETIC 130.

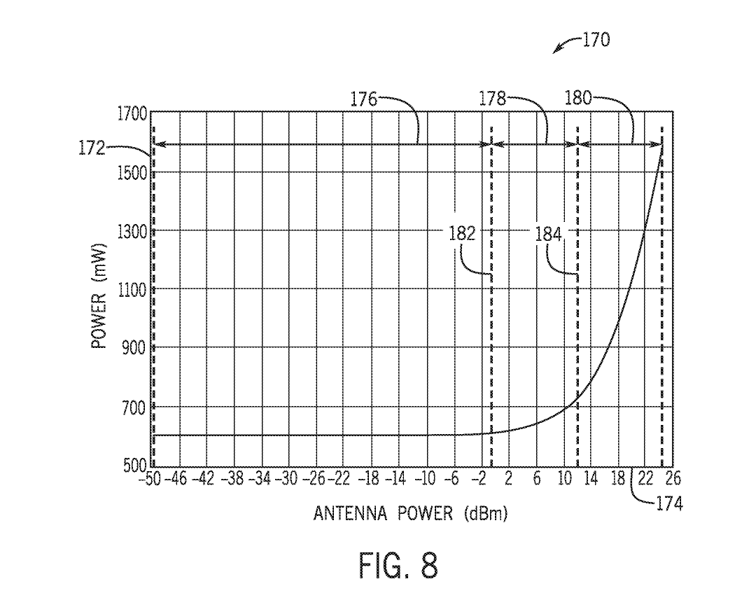

Chart 170 in FIG. 8 illustrates the DC power consumption due to signal amplification in the RF system, which may be achieved with a system capable of operating in multiple modes of operation. The power consumption 172 is charted as a function of the output antenna power 174. In a lower range 176 of the output antenna power 174, the multi-stage power amplifier 126 of the FEM 120 may operate in a fixed voltage mode, which may provide a fixed bias gain. As a result, the power consumption is not sensitive to the output antenna power 174, as the power consumption of the multi-stage power amplifier 126 remains constant. In some situations, the output antenna power may be adjusted using the pre-amplification circuitry 108. As the demand for the output antenna power 174 enters a medium range 178, the multi-stage power amplifier 126 may enter the average power tracking mode. In the average power tracking mode, multi-stage power amplifier 126 may provide higher amplification to compensate for an increase in the average output antenna power. As a result, power consumption 172 in the average power tracking mode may be more sensitive to the output antenna power 174 as the gains of multi-stage power amplifier 126 may be used to provide amplification. The power consumption 172 with respect to the output antenna power 174 may be much more sensitive in the higher range 180 for output antenna power 174, in which RF system 100 operates in the envelope tracking mode. As discussed above, the dynamic voltage supplied to the multi-stage power amplifier 126 may track the output antenna power 174 more aggressively, leading to a stronger correlation between the power consumption 172 and the output antenna power 174.

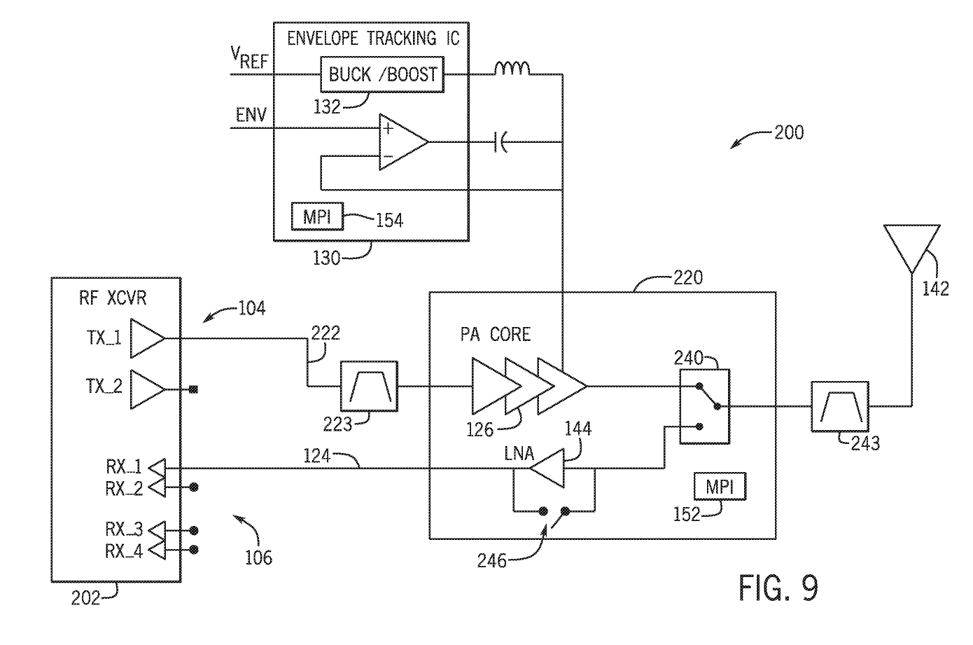

FIG. 9 illustrates an RF system 200 with an alternative architecture, which may be used by an electronic device for RF communications. RF system 200 may be used in situations where signal power requirements may be more relaxed, such as in shorter range networks, low-noise networks. The RF system 200 system that may, for example, be used by an electronic device to join a connectivity network, such as IEEE 802.11 (WiFi) or a Bluetooth network. The RF system 200 may include an RF transceiver 202. The RF transceiver 202 may have multiple TX ports 104 and multiple RX ports 106, and may be coupled to multiple FEMs to support multi-input/multi-output (MIMO) connectivity. The RF system 200 may also include a FEM 220, which is coupled to a TX port 104 via TX connection 222 and an RX port 106 via RX connection 124. Note that RF transceiver 202 may be configured to operate in multiple bandwidths. For example RF transceiver 202 may have certain TX ports 104 and RX ports 106 configured to operate using 2.4 GHz as a carrier frequency or 5 GHz as a carrier frequency. A filter bank 223 in TX connection 222 may be used to facilitate changes in the above-referred reconfiguration of transmitted carrier frequency. A second filter bank 243, disposed between the FEM 220 and the antenna may also be configured to allow appropriate signal transmission of the operational carrier frequency.

The FEM 220 may include a multi-stage power amplifier 126 similar to that of FEM 120. The multi-stage power amplifier 126 may have its gain regulated by an ETIC 130, which may provide to the FEM 220 capability to operate in an envelope tracking mode. FEM 220 may also include switching circuitry 240, which may be used to configure a coupled antenna 142 to operate in a transmitting mode or in a receiving mode. In the transmitting mode, the signal received by the RF transceiver 202 may be amplified by the multi-stage power amplifier 126, and may be provided to antenna 142. In the receive mode, a signal captured by the antenna 142 may be provided to the RF transceiver 202. In some implementations, FEM 220 may include an LNA 144 that may amplify the received signal from the antenna. The illustrated FEM 220 also includes bypass circuitry 246 that may remove the LNA 144 from the signal path. As with the RF system 100, both the ETIC 130 and the FEM 220 of the RF system 200 may be controlled using an MIPI RFFE-compliant controllers, such as controllers 152 and 154.

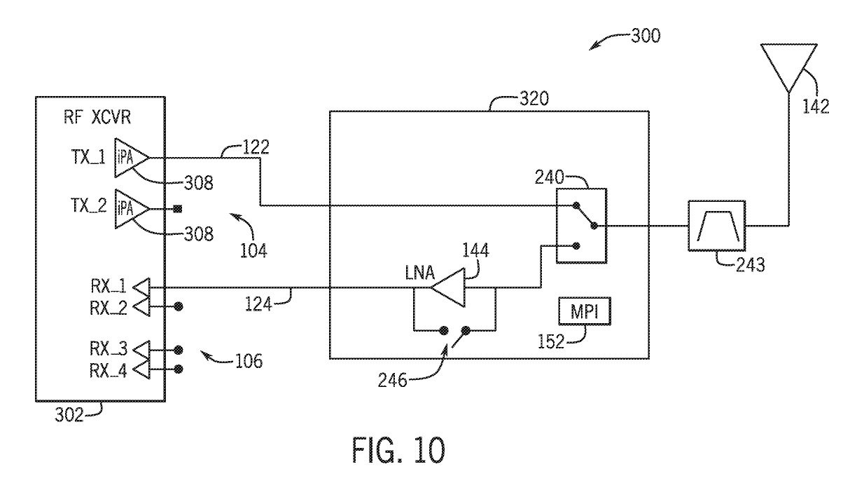

Certain electronic devices that may have more stringent power requirements may employ internal power amplifiers (iPA) to provide the transmitted signal application. The internal power amplifiers may have a gain that is substantially larger than the gain provided by a pre-amplification circuitry. For example, an internal power amplifier may provide signals with output power of up to 20 dBm, while the pre-amplification circuitry may be limited to signals with output under −10 dBm. The use of internal power amplifiers may allow a more aggressive scaling of power consumption across the operating range of the transmitter. The RF system 300, illustrated in FIG. 10, shows an architecture that may be employ internal power amplifiers to reduce power. The RF system 300 may have an RF transceiver 302 having multiple TX ports 104 and multiple RX ports 106. The TX ports 104 of the RF transceiver 302 may include internal power amplifiers 308. The RF transceiver 302 may be implemented using a semiconductor (e.g., CMOS technology) and, therefore, in RF system 300, a substantial proportion of the amplification may be provided by internal power amplifiers 308 that are implemented using CMOS technology. The RF system 300 may also include a FEM 320. In contrast with FEMs 120 and 220 of FIGS. 7 and 8, respectively, the FEM 320 may provide an outgoing signal to the antenna without employing a PA. In such system, the regulation of the amplification gain and any power tracking and/or envelope tracking may be provided by internal power amplifier 308. The FEM 320 may include switching circuitry 240 to configure the antenna 142 to receive or transmit signals. The FEM 320 may include a LNA 144 circuitry to amplify an incoming signal received from antenna 142 and a bypass circuitry 246 to bypass LNA 144 in the RX signal path. The FEM 320 may also include a controller 152, which may be compliant with an MIPI RFFE-standard, as discussed above. In some implementations, RF system 300 may be configured to operate in multiple bands (e.g., carrier frequencies). A configurable filter bank 243 may be used to facilitate reception in the configured carrier frequency by filtering out signals and noise sent and received by antenna 142 that may be outside the allowed frequencies.

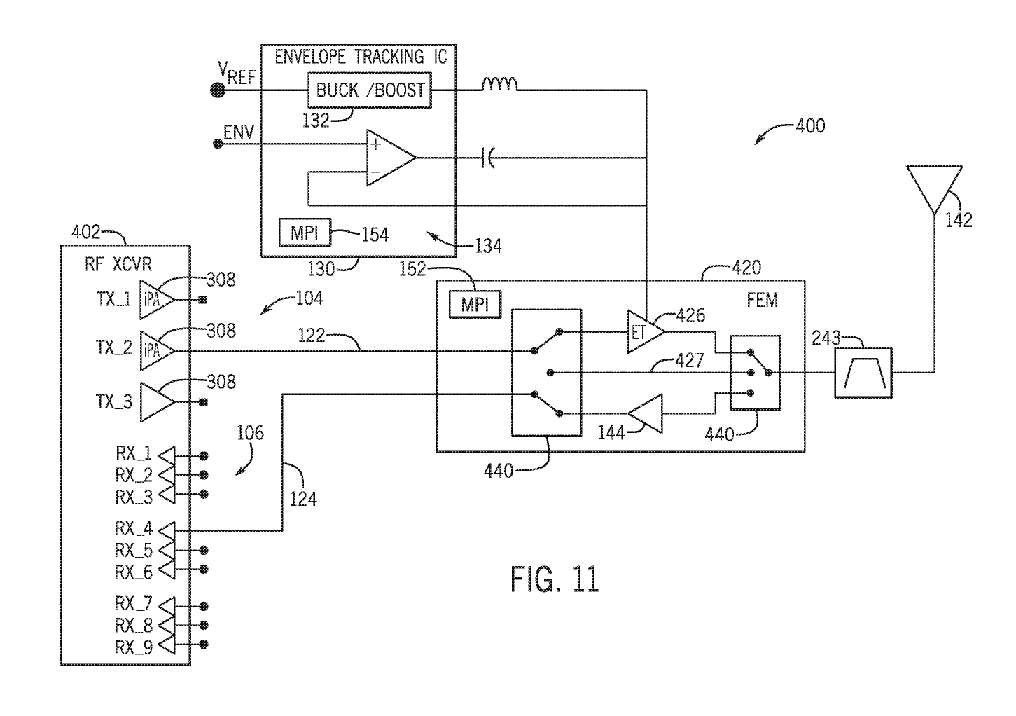

As discussed above, an electronic device may be used to join multiple networks having different signal power constraints. The integrated RF system 400 in FIG. 11 may be used by such electronic devices to employ larger PAs to achieve higher signal power and deactivate PAs if they are not used. The RF system 400 may include an RF transceiver 402. The RF transceiver 402 may have multiple TX ports 104 and multiple RX ports 106, and may be configured to couple to multiple FEMs to support MIMO and/or multi-band communication. Moreover, the TX ports 104 of RF transceiver 402 may include multiple internal power amplifiers 308 which may be configured to provide substantial amplification.

In the illustrated RF system 400, the RF transceiver 402 is coupled to a FEM 420 via TX connection 122 and RX connection 124. The FEM 420 may have a PA 426 that may be used to amplify received signals from the RF transceiver 402. In some implementations, PA 426 may be a single-stage amplifier, in contrast with the multi-stage PA 126 illustrated in the systems of FIGS. 7 and 9. The single-stage PA 426 may provide sufficient gain, as signal coming from the RF transceiver 402 may already be amplified by internal power amplifier 308. The single-stage PA 426 may implement an envelope tracking mode by receiving power from an ETIC 130 configured to provide the envelope tracking. The ETIC 130, as discussed above, may include a buck/boost circuitry 132 coupled to an error tracking circuitry 134 which may receive an envelope signal as tracking signal 136. The FEM 420 may also include an LNA 144, which may be used to amplify signals received from the antenna 142 and transmitted to the RF transceiver 402.

The FEM 420 may also include a bypass line 427, which may be used to bypass the single-stage PA 426 or the LNA 144 during transmission and/or reception, respectively. Switching circuitry 440 may be used to facilitate this configuration by coupling the amplification or the bypass circuitry to the signal path as appropriate. The FEM 420 and the ETIC 130 may include controllers 152 and 154 that may be used to provide configuration instructions and to coordinate the operation of the components of RF system 400.

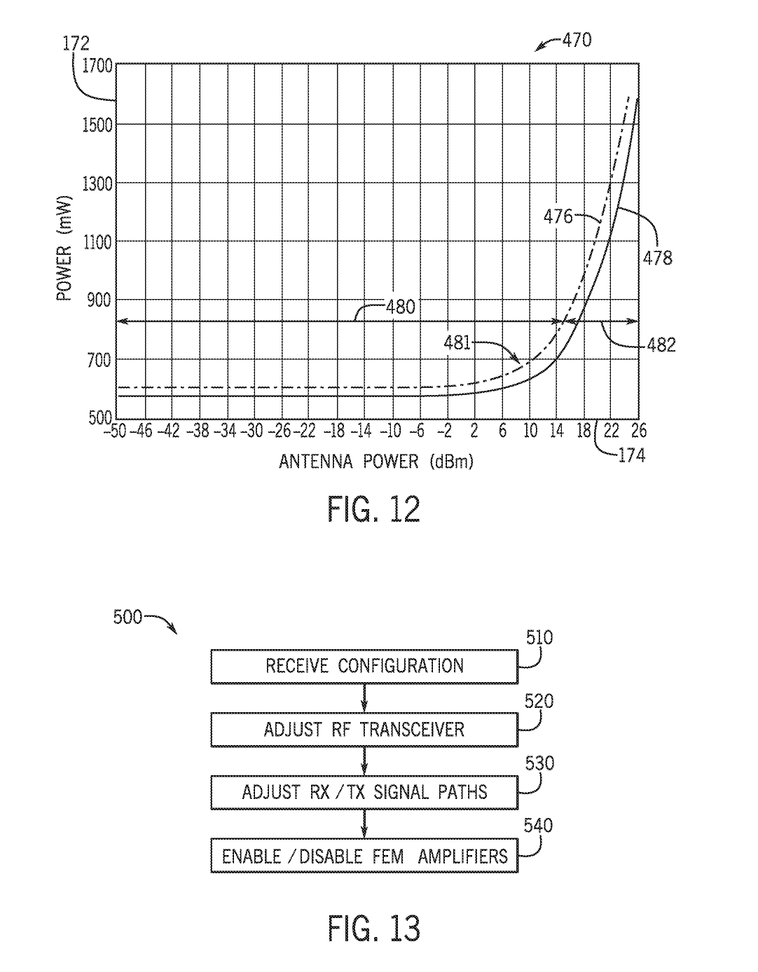

The use of semiconductor based internal power amplifiers (iPAs), as well as the architecture that includes the switching circuitry 440, the single-stage PA 426 may lead to a reduced power consumption over a broad range, when compared to an RF system such as that illustrated in FIG. 7 or 9, while allowing substantial signal power, in contrast with a system such as that illustrated in FIG. 10. This performance change is illustrated in chart 470 in FIG. 12. Chart 470 illustrates the power consumption 172 in function of the output antenna power 174 for a multi-stage power amplifier system (curve 476) and an internal power amplifier system (curve 478). Note that throughout the operating range of the system, an internal power amplifier system may provide better power consumption 172 performance than the multi-stage power amplifier system. In the lower range 480 for output antenna power 174, RF system 400 may operate in an internal power amplifier mode (e.g., iPA mode), in which the internal power amplifier provides the signal application, bypassing the single-stage amplifier. By deactivating and bypassing the power amplifier in the front-end module, system 450 may reduce the baseline power consumption, in contrast with the fixed voltage mode employed by an RF system 100, as discussed above. At a moderate output antenna power 174 (region 481), the internal power amplifier may aggressively scale power consumption, without resorting to an average power tracking mode, and thus, the power amplifier in the front-end module may remain deactivated.

At higher output antenna power 174 (region 482), the front-end module may be reconfigured to include the single-stage power amplifier. Note that in such situation, the internal power amplifier in the transceiver may effectively operate as the power driver to the PA in the front-end module. The internal power amplifier may provide higher efficiency than a driver of a multi-stage power amplifier, and thus, the RF system 400 may operate more efficiently in the envelope tracking mode.

The flow chart in FIG. 13 illustrates a method 500 to operate a configurable RF communication system such as RF systems 100, 200, 300, or 400. Method 500 may include a process 510 to receive a configuration of the signal being transmitted and/or received by the antenna. The configuration may describe a channel, which may include a band specification (e.g., carrier frequency) and/or a time division slot multiplexing configuration. The configuration may also include a modulation, which may be an amplitude modulation (AM), a frequency modulation (FM), a quadrature amplitude modulation (QAM), a frequency-shift keyring (FSK) modulation, or any other appropriate modulation. In a process 520, the RF transceiver circuitry may be adjusted to process an outgoing and/or incoming signal based on the signal band, modulation, and time coding. For certain systems, such as RF system 100, the RF transceiver may adjust its pre-amplification gain for an outgoing signal. In systems having an internal power amplifier in its circuitry, such as RF systems 300 of FIG. 10 and 400 of FIG. 11, the internal power amplifier may be adjusted to provide an amplification gain, as discussed above.

In a process 530 the signal paths of the front-end modules may be adjusted. Using switching circuitry, the signal path may be adjusted to include amplifiers, such as an LNA in the RX signal path and/or a power amplifier in the TX signal path. The switching circuitry may also be adjusted to select appropriate filters from the filter banks, according to the signal band. The switching circuitry may also configure to couple an antenna to either the RX signal path or the TX signal path. In some implementations, such as when the RF communication system is operating using a time-domain coding, switching circuitry of the front-end module may be used to implement the time-multiplexing operation.

In a process 540, the amplifiers in the front-end module may be enabled and/or disabled. For example, if a RX signal path is configured to bypass the LNA, the LNA may be disabled to conserve power. In the RF system 400 of FIG. 11, which may be configured to bypass the FEM power amplifier as discussed above, the single-stage PA 426 and the ETIC 130 may be disabled when the system is not operating in envelope tracking mode. In RF system 100, the ETIC 130 may be adjusted to switch between an envelope tracking mode and the average power tracking mode by adjusting the tracking signal 136. Implementation of processes 530 and 540 may be facilitated by the use of an MIPI RFFE-compliant controllers in the FEM and/or the ETIC, as discussed above.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

1. An electrical device comprising:
a radio frequency (RF) transceiver comprising an internal power amplifier coupled to a transmit (TX) port of the RF transceiver;
a front-end module comprising a power amplifier coupled to the TX port of the RF transceiver, wherein the front-end module is configured to couple to an antenna; and
switching circuitry configured to bypass the power amplifier of the front-end module.

2. The electrical device of claim 1, wherein the power amplifier is powered by envelope tracking circuitry.

3. (canceled)

4. The electrical device of claim 1, wherein the front-end module comprises a controller configured to select a mode of operation from a set of modes of operation.

5. The electrical device of claim 4, wherein the set of modes of operation comprises:
an internal power amplifier mode, wherein the front-end module is configured to disable the power amplifier; and
an envelope tracking mode, wherein a voltage supplied to the power amplifier is dynamically adjusted to follow the envelope of an output RF signal.

6. The electrical device of claim 4, wherein the controller is a Mobile Industry Processor Interface RF Front-End Interface (MIPI RFFE) controller.

7. The electrical device of claim 1, wherein the front-end module comprises a configurable filter bank configured to filter a transmitted signal to the antenna, or a received signal from the antenna, or both.

8. The electrical device of claim 1, wherein the front-end module comprises a low-noise amplifier coupled to a receive (RX) port of the transceiver.

9. The electrical device of claim 1, wherein the internal power amplifier is configured to provides an output signal up to 20 dBm.

10. The electrical device of claim 1, wherein the internal power amplifier comprises a complementary metal-oxide semiconductor (CMOS) amplifier.

11. A front-end module of a radio frequency RF communication system configured to couple to a radio frequency (RF) transceiver and to an antenna, the front-end module comprising:
a power amplifier configured to provide a gain to an outgoing signal received from the RF transceiver;
switching circuitry configured to bypass the power amplifier; and
control circuitry configured to adjust the switching circuitry and the power amplifier based on a target output signal power.

12. The front-end module of claim 11, wherein the power amplifier comprises a single-stage power amplifier, and wherein the RF transceiver comprises an internal power amplifier configured to provide driver amplification to the outgoing signal.

13. The front-end module of claim 11, wherein the power amplifier is coupled to an envelope tracking integrated circuit.

14. The front-end module of claim 13, wherein the envelope tracking integrated circuit comprises control circuitry.

15. The front-end module of claim 14, wherein the control circuitry of the front-end module and the control circuitry of the envelope tracking circuitry comprise a Mobile Industry Processor Interface RF Front-End Interface (MIPI RFFE).

16. The front-end module of claim 11, wherein the front-end module comprises a low-noise amplifier configured to provide a gain to an incoming signal received from the antenna and the switching circuitry is configured to bypass the low-noise amplifier.

17. A method for controlling a radio frequency (RF) communication system, comprising:
adjusting modulation circuitry of an RF transceiver of the RF communication system based on a channel specification of a first network of a set of networks;
switching a signal path of a front-end module of the RF communication system to bypass a power amplifier of the front-end module based on the channel specification of the first network or an output signal power specification of the first network, or both, wherein the signal path is configured to couple the RF transceiver to an antenna; and
configuring at least one amplifier of the front-end module based on the output signal power specification of the first network.

18. The method of claim 17, wherein the first network comprises a cellular network, a Bluetooth network, an IEEE 802.3 network, or any combination thereof.

19. The method of claim 17, wherein the channel specification comprises a carrier frequency of a band of the first network, a time-coding system, a time-multiplexing, system, or any combination thereof.

20. The method of claim 17, wherein configuring the at least one amplifier of the front-end module comprises disabling the power amplifier of the front-end module.

21. The method of claim 17, wherein switching the signal path comprises selecting a filter of a filter bank of the front-end module.

22. The method of claim 17, wherein switching the signal path comprises coupling the antenna to a receive (RX) port of the RF transceiver or coupling the antenna to transmit (TX) port of the RF transceiver.

23. The method of claim 17, wherein configuring the at least one amplifier comprises operating a power amplifier in an envelope tracking mode.

24. The method of claim 17, wherein configuring the at least one amplifier comprises operating a power amplifier in an average power tracking mode.

25. The method of claim 17, comprising adjusting an internal power amplifier of the RF transceiver based on the output signal power specification of the first network.
